(19) United States
(12) Patent Application Publication
(10) Pub. No.: US 2015/0091154 A1
(43) Pub. Date: Apr. 2, 2015

(54) SUBSTRATELESS PACKAGES WITH SCRIBE DISPOSED ON HEAT SPREADER

(71) Applicants: Macrotech Technology Inc., Hsinchu City (TW); Powertech Technology Inc., Hsinchu (TW)

(72) Inventor: Hung-Hsin HSU, Hsinchu (TW)

(73) Assignees: Macrotech Technology Inc., Hsinchu City (TW); Powertech Technology Inc., Hsinchu (TW)

(21) Appl. No.: 14/041,391

(22) Filed: Sep. 30, 2013

(51) Int. Cl. H01L 23/34; H01L 23/544

(52) U.S. Cl. CPC H01L 23/34; H01L 23/544
USPC 257/712

(57) ABSTRACT

Disclosed is a substrateless semiconductor package having a plurality of scribe lines formed on a heat spreader, primarily comprising the heat spreader, a chip disposed on the heat spreader and an encapsulant. Formed on a thermally dissipating surface of the heat spreader are a plurality of scribe line grooves with a plurality of openings formed inside to penetrate through the die-attaching surface of the heat spreader. The chip is disposed on the die-attaching surface and the encapsulant is formed on the die-attaching surface to encapsulate a first surface of the chip on which a plurality of external pads are formed Without being covered by the encapsulant. Therein, the encapsulant is filled in the scribe line grooves via the openings so that a scribe line pattern exposed from the thermally dissipating surface is formed.

### FIELD OF THE INVENTION

The present invention relates to a semiconductor package and more specifically to a substrateless semiconductor package with a plurality of scribe lines disposed on its heat spreader.

### BACKGROUND OF THE INVENTION

Recently, flip-chip packages with heat spreaders are gradually implemented where heat spreaders are disposed on the external surfaces of the encapsulant of flip-chip packages. There are two more popular package structures. One is to attach a heat ii spreader to the external surface of the encapsulant by thermal interface materials (TIM) after flip-chip die bonding and molding, however, the cost will be high and the package warpage has to be under a specific control. The other e is to dispose a heat spreader on a substrate or on a chip after flip-chip die bonding and before molding, then place into a mold chest for molding to form an encapsulant between the substrate and the heat spreader where the encapsulant encapsulates the internal surface of the heat spreader, however, the coplanarity between the substrate and the heat spreader has to be tightly controlled where any warpage of tile substrate will lead to encapsulant bleeding to the external surface of the heat spreader. Furthermore, alignment marks for singulation are formed on the circuitry of the substrate.

In Taiwan Patent No. I245350, “Wafer level semiconductor package with build-up layer”, Hung et al. taught a wafer level semiconductor packages With built-up layers including a rigid base, a rigid frame with through holes fixed on the rigid base, and chips accommodated inside the through holes of the rigid frame where the gaps between the chips and the rigid frame were filled with interface materials and a built-up layer is formed on the chips and the rigid frame to electrically connect to the chips to replace substrates where the material of the rigid frame can be metal. Even though substrates and underfill materials were eliminated from the conventional flip-chip packages, however, additional tooling was needed such as rigid frames, interface materials, and built-up layers. Moreover, it is very difficult to perform accurate singluation after the formation of built-up layers since there is no substrate with alignment keys for singulation.

### SUMMARY OF THE INVENTION

The main purpose of the present invention is to provide a substrateless semiconductor package with scribe lines disposed on a heat spreader to eliminate the cost of substrates and underfill with clear alignment marks for singulation to meet the requirements of smaller footprint and higher heat dissipation.

Another purpose of the present invention is to provide a substrateless semiconductor package with scribe lines disposed on a heat spreader without molding compound bleeding, large package warpage, high heat resistance due to poor coplanarity between a substrate and a heat spreader to further save the package cost.

The third purpose of the present invention is to provide a substrateless semiconductor package with scribe lines disposed on a heat spreader to improve delamination of the heat spreader from the top surface of the encapsulant during singulation or end user operation.

According to the present invention, a substrateless semiconductor package with a plurality of scribe lines disposed on a heat spreader is revealed, primarily comprising a heat spreader, a chip, and an encapsulant. The heat spreader has a heat dissipating surface and a die attaching surface where a plurality of scribe lien grooves are disposed on the heat spreader, moreover, a plurality of first openings are disposed inside the scribe line grooves so that the scribe line grooves are physically connected to the die attaching surface. The chip is disposed on the die attaching surface of the heat spreader where a plurality of external pads are disposed on a first surface of the chip away from the heat spreader. The encapsulant is formed on the die attaching surface of the heat spreader to encapsulate the first surface of the chip without covering the external pads. Moreover, the encapsulant is also filled in the scribe line grooves by flowing through the first openings in a manner to form a scribe line pattern exposed from the heat dissipating surface. The manufacture method of the substrateless semiconductor package is also revealed in the present invention.

### DESCRIPTION OF THE DRAWINGS

FIG. 1 is a cross-sectional view of a substrateless semiconductor package with a plurality of scribe lines disposed on a heat spreader according to the first embodiment of the present invention.

FIG. 2 is a top view showing a first redistribution layer disposed on the first surface of the chip of the substrateless semiconductor package according to the first embodiment of the present invention.

FIGS. 3A to 3F are component cross-sectional views showing each processing step during the manufacture processes of the substrateless semiconductor package according to the first embodiment of the present invention.

FIGS. 4A and 4B are a three-dimensional view showing the heat dissipating surface of the heat spreader after die bonding and before package singulation and a top view showing the die attaching surface of the heat spreader for the substrateless semiconductor package respectively according to the first embodiment of the present invention.

FIG. 5 is a cross-sectional view along the dashed line 5-5 of FIG. 4A showing the scribe line grooves of the heat spreader for the substrateless semiconductor package according to the first embodiment of the present invention.

FIG. 6 is a cross-sectional view of another substrateless semiconductor package according to the second embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

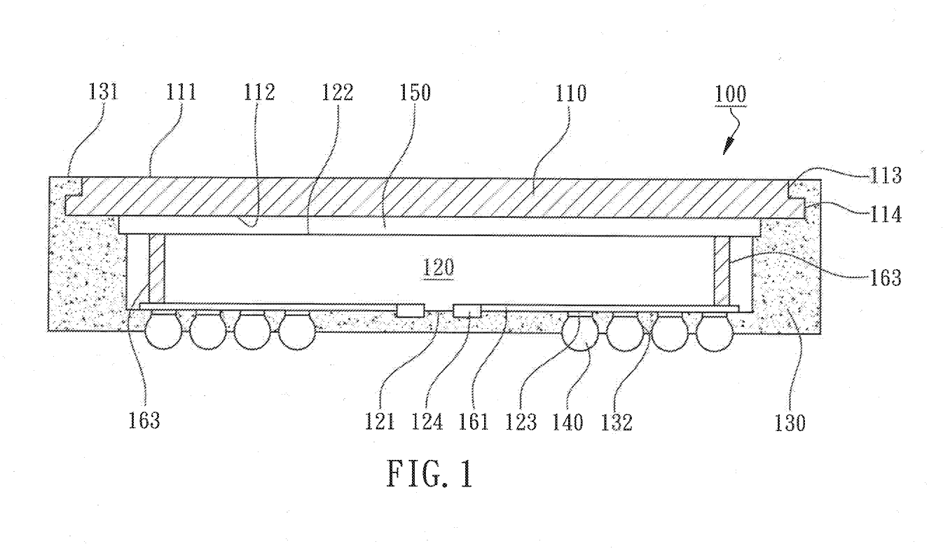

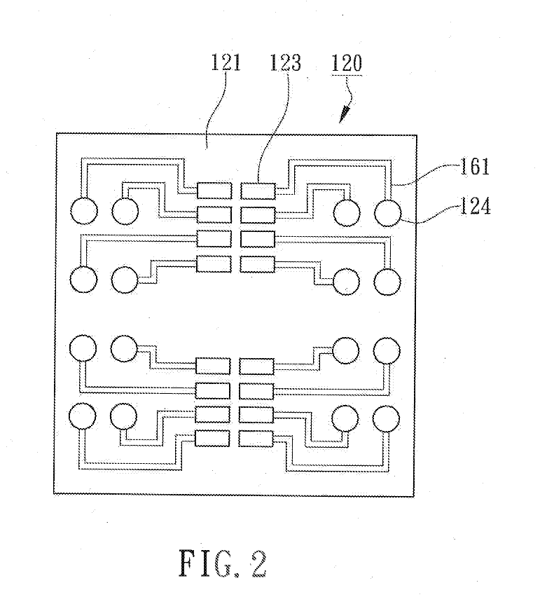

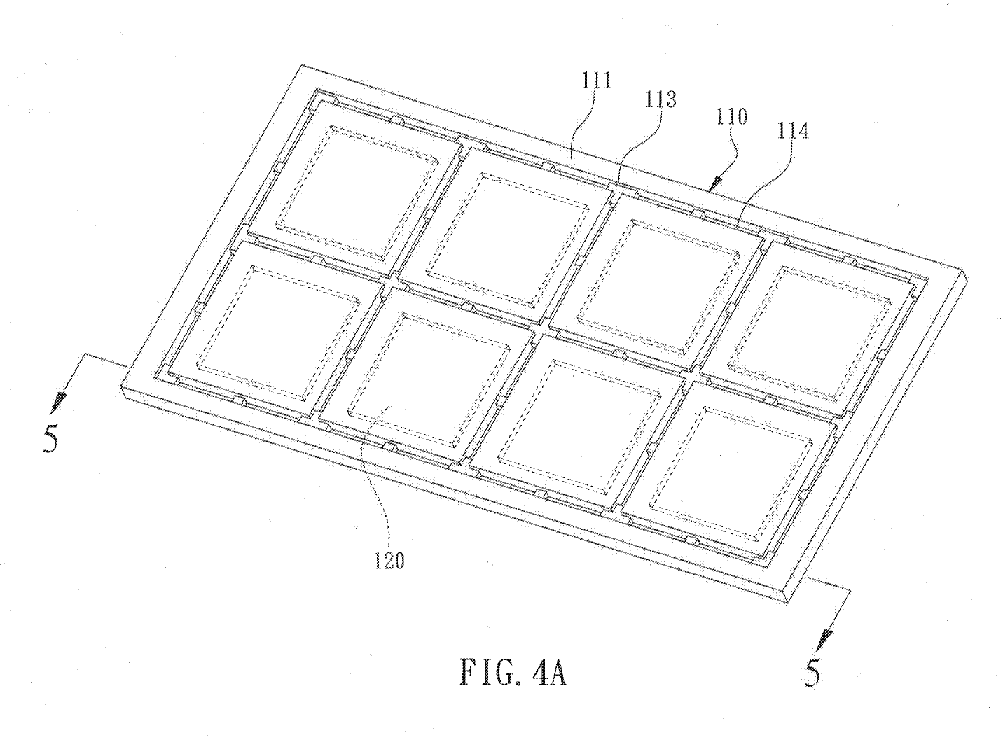

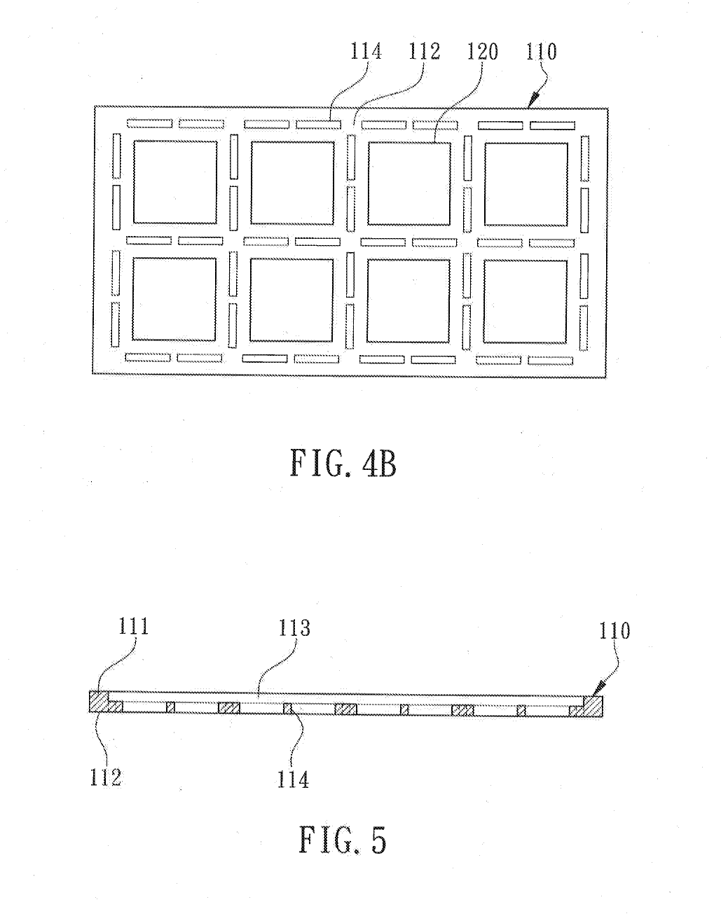

According to the first embodiment of the present invention, a substrateless semiconductor package 100 with a plurality of scribe lines disposed on a heat spreader is illustrated in FIG. 1 for a cross-sectional view. The substrateless semiconductor package 100 primarily comprises a heat spreader 110, a chip 120, and an encapsulant 130. There is no wiring substrate in the package 100 to carry the chip 120. The chip 120 has a first surface 121 and a second surface 122 where, to be more specific, the first surface 121 is the active surface of the chip 120 and the second surface 122 is the backside of the chip 120. The top view of the first surface is illustrated in FIG. 2. The heat spreader 110 has a heat dissipating surface 111 and a die attaching surface 112. FIG. 4A and FIG. 4B are a three-dimensional view of the heat spreader 110 after die-bonding the chip 120 and before package singulation to show the heat dissipating surface 111 and a top view of the die attaching surface 112 of the heat spreader 110 respectively and FIG. 5 is a cross-sectional view of the heat spreader 110 along the dashed line 5-5 in FIG. 4A.

The heat spreader 110 can be a copper (Cu) metal plate with plated Nickel (Ni) surface finish. A plurality of scribe line grooves 113 are formed on the heat dissipating surface 111 of the heat spreader 110 where the depth of the scribe line grooves 111 is about or less than half of the thickness of the heat spreader 110. A plurality of first openings 114 are disposed inside the scribe line grooves 113 so that the scribe line grooves 113 are physically connected to the die attaching surface 112. In the present package structure, the scribe line grooves 113 are interconnected to form as a rectangle ring of a checker hoard. The first openings 114 can be shaped as alignment marks penetrating through the heat spreader 110 as shown in FIG. 4A and FIG. 4B. In a more specific structure, the scribe line grooves 113 can be cut into a closed loop located at the peripheries of the heat spreader 110 corresponding to each semiconductor package. Preferably, the first openings 114 include a plurality of alignment holes located at the corners of the closed loop with the shape of “L” or “T” as shown in FIG. 4A.

The chip 120 is a semiconductor component with fabricated IC circuitry. The chip 120 is disposed on the die attaching surface 112 of the heat spreader 110 where a plurality of external pads 123 are disposed on the first surface 121 of the chip 120 away from the hear spreader 110. As shown in FIG. 1 and FIG. 2 again, a first redistribution layer 161 is disposed on the chip 120 to electrically connect a plurality of bonding pads 124 of the chip 120 to the external pads 123 so that the pitch of the external pads 123 can be larger than the pitch of the bonding pads 124 where the bonding pads 124 are the original electrical terminals of the IC circuitry disposed on the active surface of the chip 120. The first distribution layer 161 is directly fabricated on the chip 120 by IC fabrication processes such as PVD, CVD, sputter, or plating with the corresponding wafer-level etching processes. Furthermore, the first redistribution layer 161 and the bonding pads 124 can be formed on the first surface 121 of the chip 120 to provide heat dissipating paths from the first surface 121 of the chip 120 to the heat spreader 110 when a plurality of thermal vias 163 are built inside the chip 120. In a more specific package structure, the substrateless semiconductor package 100 further comprises a non-conductive layer 150 such as epoxy adhesive or PI tape formed between the die attaching surface 112 of the heat spreader 110 and the second surface 122 of the chip 120 to avoid leakage current from the chip 120 to the heat spreader 110. However, alternatively, a conductive adhesive layer can be disposed between the chip 120 and the heat spreader 110 such as Au to Si or Al to Si eutectic bonding layers to further enhance heat dissipating efficiency.

The encapsulant 130 can be thermosetting isolated materials such as EMC formed by molding or light-reactive isolated materials. But, without any restriction, the encapsulant 130 can be formed by printing or dispensing. The encapsulant 130 is disposed on the die attaching surface 112 of the heat spreader 110 to encapsulate the first surface 121 of the chip 120 without covering the external pads 123, moreover, the encapsulant 130 flows through the first openings 114 to fill in the scribe line grooves 113 so that a scribe line pattern 131 is formed to expose from the heat spreader 111. Since the colors are very different between the heat spreader 110 made of metal and the scribe line pattern 131 formed by encapsulant 130, therefore, optical inspection mechanism will quickly and easily be able to detect the scribe lines for package singluation to eliminate the conventional alignment marks formed by the circuitry of the substrate.

Preferable, the thickness of the encapsulant 130 on the heat spreader 110 can be greater than the thickness of the chip 120 on the heat spreader 110 so that the encapsulant 130 is able to completely encapsulate the chip 120 where the encapsulant 130 also covers the sides of the chip 120 between the first surface 121 and the second surface 122 to achieve better protection of the chip 120. Moreover, the encapsulant 130 has a plurality of second opening 132 to expose the external pads 123. Therefore, a plurality of external terminals 140 are jointed to the external pads 123 through the second openings 132 and extruded from the encapsulant 130. The external terminals 140 can be solder balls, or pillars, conductive paste, or solder paste.

Therefore, the first embodiment of the present invention has provided a substrateless semiconductor package with the scribe lines disposed on the heat spreader to eliminate the cost of substrates and underfill with good alignment marks for package singulation to meet the requirements of smaller footprint and higher heat dissipation without molding compound bleeding, large package warpage, high heat resistance due to poor coplanarity between a substrate and a heat spreader to further save the package cost and to improve conventional delamination of a heat spreader from the top surface of the encapsulant during singulation or end user operation.

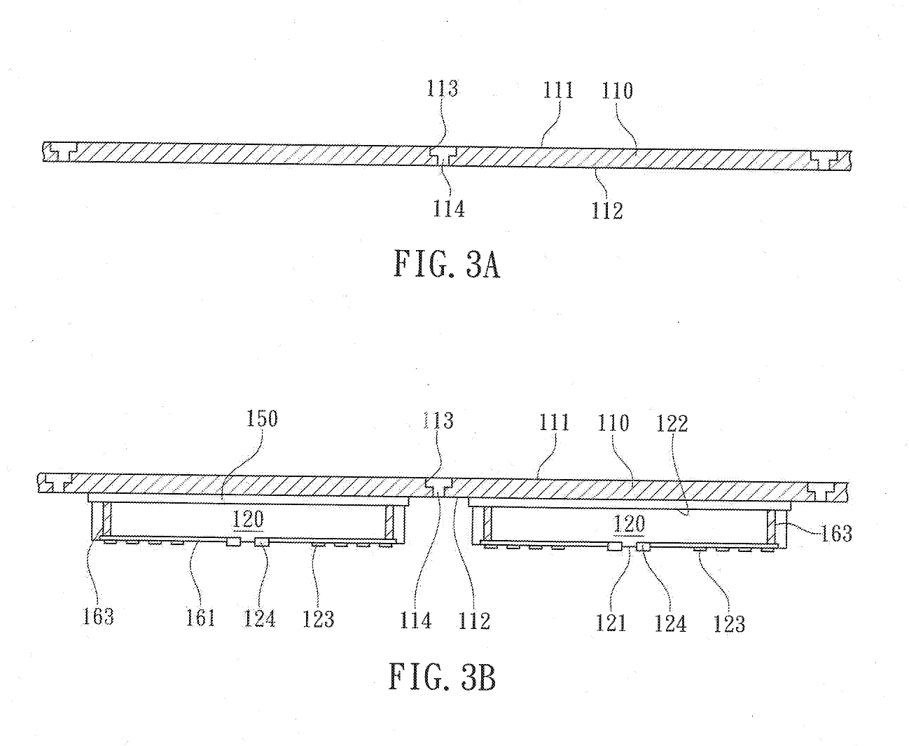

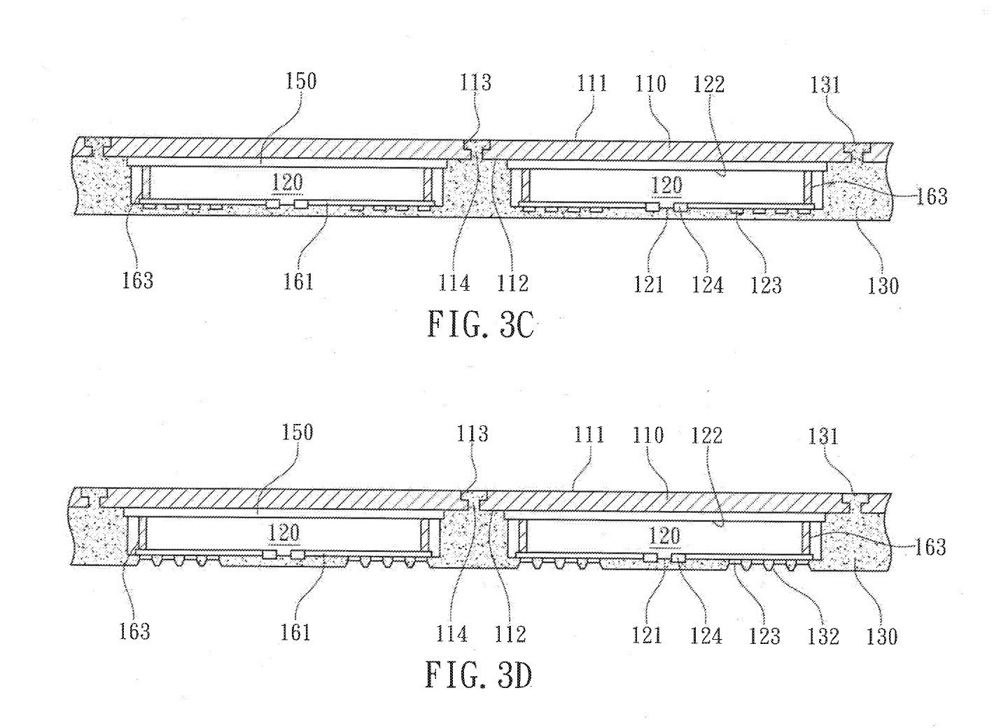

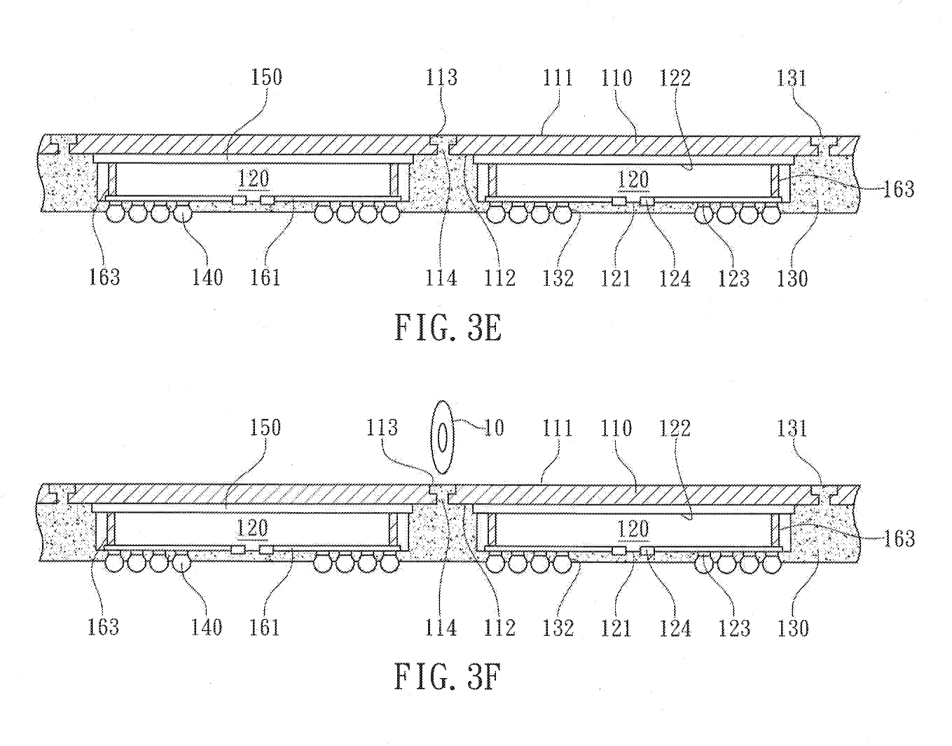

As shown from FIG. 3A to 3F, the manufacture method of the substrateless semiconductor package 100 is also revealed in the present invention. Firstly, as shown in FIG. 3A as well as in FIG. 4A, FIG. 4B, and FIG. 5, a plurality of heat spreaders 110 each having a heat dissipating surface 111 and a die attaching surface 112 are provided by a matrix sheet. A plurality of scribe line grooves 113 are formed on the heat dissipation surface 111 where a plurality of first openings 114 are disposed inside the scribe line grooves 113 to physically connect to the die attaching surface 112. As shown in FIG. 3A, the width of the scribe line grooves 113 is greater than the diameter of the first openings 114 so as to show that the first openings 114 are located inside the bottom of the scribe line grooves 113 and are completely exposed from the die attaching surface 112. That is easy to clearly illustrate the differences between grooves and openings. However, in practical implementation, the width of the scribe line grooves 113 and the diameter of the first openings 114 can be the same as shown in FIG. 4A. Then, as shown in FIG. 3B, a plurality of chips 120 are attached on the die attaching surfaces 112 of the heat spreaders 110 where a plurality of external pads 123 are disposed on the first surface 121 of each chip 120 away from the corresponding heat spreader 110 so that there is no need for a substrate to carry the chips. Then, as shown in FIG. 3C, an encapsulant 130 is formed on the die attaching surfaces 112 of the heat spreaders 110 by transfer molding to encapsulate the chips 120 where the encapsulant 130 would flow through the first openings 114 and till inside the scribe line grooves 113 to form a scribe line pattern 131 exposed from each heat spreader 110. In the present step, the encapsulant 130 filled inside the scribe line grooves 112 can be interconnected to each other to form a scribe line pattern 131. Moreover, in the present embodiment, the thickness of the encapsulant 130 over the heat spreaders 110 can be greater than the thickness of the chips 120 over the heat spreaders 110 so that the encapsulant 130 can completely encapsulate the first surfaces 121 of the chips 120. Then, as shown in FIG. 3D, a plurality of second openings 132 are formed on the encapsulant 130 by through mold via (TMV) technology so that the encapsulant 130 does not cover the external pads 123. Then, as shown in FIG. 3E, a plurality of external terminals 140 are jointed to the external pads 123 and extruded from the encapsulant 130 by ball placement and reflow. In a various embodiment, the external terminals 140 can be jointed first followed by the formation of the encapsulant 130. The encapsulant 130 can be formed by printing or dispensing. Finally, as shown in FIG. 3F, a singulating tool 10 such as a dicing blade or a cutting laser singulates the heat spreaders 110 and the encapsulant 130 along the center lines of the scribe line pattern 131 to manufacture a plurality of individual substrateless semiconductor packages 100 as shown in FIG. 1.

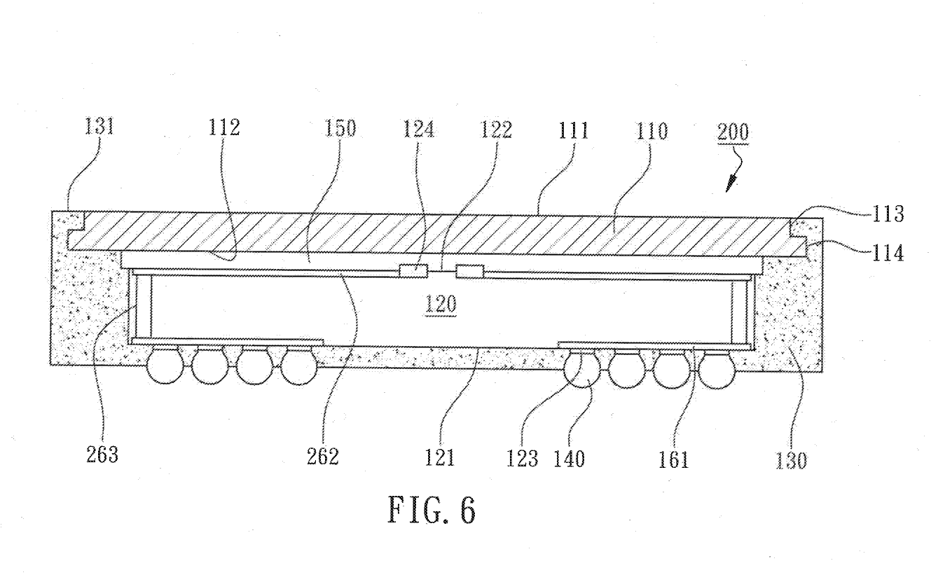

According to the second embodiment of the present invention, another substrateless semiconductor package 200 with a plurality of scribe lines disposed on a heat spreader is illustrated in FIG. 6 for a cross-sectional view. The substrateless semiconductor package 200 primarily comprises a heat spreader 110, a chip 120, and an encapsulant 130. The chip 120 has a first surface 121 and a second surface 122 where, to be more specific, the first surface 121 is the backside of the chip 120 and the second surface 122 is the active surface of the chip 120. The heat spreader 110 has a heat dissipating surface 111 and a die attaching surface 112. A plurality of scribe line grooves 113 are formed on the heat dissipating surface 111 of the heat spreader 110 where a plurality of first openings 114 are formed inside the scribe line grooves 113 to penetrate through the heat spreader 110 so that the scribe line grooves 113 are physically connected to the die attaching surface 112. The second surface 122 of the chip 120 is attached onto the die attaching surface 112 of the heat spreader 110 where a plurality of external pads 123 are disposed on the first surface 121 of the chip 120 away from the heat spreader 110. The encapsulant 130 is formed on the die attaching surface 112 of the heat spreader 110 to encapsulate the chip 120 without encapsulating the external pads 123 where the encapsulant 130 flows through the first openings 114 and is filled in the scribe line grooves 113 to form a scribe line pattern 131 exposed from the heat dissipating surface 111.

In the present embodiment, at least a first redistribution layer 161 is disposed on the first surface 121 of the chip 120 to electrically connect a plurality of bonding pads 124 of the chip to the external pads 123 so that the pitch of the external pads 123 is larger than the pitch of the bonding pads 123. To be more specific, the bonding pads 124 are formed on the second surface 122 of the chip 120. A second redistribution layer 262 is also formed on the second surface 122 of the chip 120 and a plurality of TSV 263 are formed inside the chip 120 penetrating from the first surface 121 to the second surface 122 to electrically connect the external pads 123 to the first redistribution layer 161 and also to provide heat dissipating paths from the heat spreader 110 to the first surface 121 of the chip 120.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A substrateless semiconductor package comprising:
a heat spreader having a heat dissipating surface and a die attaching surface, wherein a plurality of scribe line grooves are formed on the heat dissipating surface, wherein a plurality of first openings are formed inside the scribe line grooves so that the scribe line grooves are physically connected to the die attaching surfaces;
a chip disposed on the die attaching surface of the heat spreader, wherein a plurality of external pads are formed on a first surface of the chip away from the heat spreader; and
an encapsulant formed on the die attaching surface of the heat spreader to encapsulate the first surface of the chip without encapsulate the external pads, wherein the encapsulant is also filled in the scribe line grooves by flowing through the first openings in a manner to form a scribe line pattern exposed from heat dissipating surface.

2. The substrateless semiconductor package as claimed in claim 1, wherein the scribe line grooves are interconnected to each other to form as a shape of a rectangle ring of a checker board.

3. The substrateless semiconductor package as claimed in claim 2, wherein the scribe line grooves are formed as a closed loop at the peripheries of the heat spreader.

4. The substrateless semiconductor package as claimed in claim 1, wherein a first redistribution layer is formed on the first surface of the chip to electrically connect a plurality of bonding pads of the chip to the external pads.

5. The substrateless semiconductor package as claimed in claim 4, wherein the bonding pads are also formed on the first surface of the chip.

6. The substrateless semiconductor package as claimed in claim 5, wherein a plurality of thermal vias are built inside the chip,

7. The substrateless semiconductor package as claimed in claim 4, wherein the bonding pads are formed on a second surface of the chip attached to the die attaching surface, wherein a second redistribution layer is disposed on the second surface of the chip and a plurality of TSVs are formed inside the chip penetrating from the first surface to the second surface so that the bonding pads are electrically connected to the first redistribution layer.

8. The substrateless semiconductor package as claimed in claim 1, wherein the thickness of the encapsulant above the heat spreader is larger than the thickness of the chip disposed on the heat spreader so that the encapsulant completely encapsulates the chip, where a plurality of second openings are formed in the encapsulant to expose the external pads.

9. The substrateless semiconductor package as claimed in claim 8, further comprising a plurality of external terminals jointed to the external pads through the second openings and extruded from the encapsulant.

10. The substrateless semiconductor package as claimed in claim 1, further comprising a non-conductive adhesive layer formed between the die attaching surface of the heat spreader and a second surface of the chip.

11. The substrateless semiconductor package as claimed in claim 1, wherein the width of the scribe line grooves is not smaller than the diameter of the first openings.

12. The substrateless semiconductor package as claimed in claim 1, wherein the first openings includes a plurality of alignment holes.
